(19) United States
(12) Patent Application Publication
(10) Pub. No.: US 2025/0040091 A1
(43) Pub. Date: Jan. 30, 2025

(54) WATER-COOLED HEAT DISSIPATION DEVICE

(71) Applicant: YUNG SHEN SU, NEW TAIPEI CITY (TW)

(72) Inventor: YUNG SHEN SU, NEW TAIPEI CITY (TW)

(21) Appl. No.: 18/460,205

(22) Filed: Sep. 1, 2023

(30) Foreign Application Priority Data
Jul. 28, 2023 (TW) 112207980

(51) Int. Cl. H05K 7/20

(52) U.S. Cl. CPC H05K 7/20318; H05K 7/20309

(57) ABSTRACT

A water-cooled heat dissipation device for cooling electronic devices and includes an evaporator, a water cooler, and at least one condensation tube. The condensation tube extends upward and inclinedly into the water cooler, and is submerged in cooling water. By utilizing the inclined placement of the condensation tube and an independent water cooler, the medium within the evaporating chamber evaporates from liquid state to gas state. The condensation tube directs the vapor upwards into the cooling chamber for cooling, where the gas condenses back into liquid. The liquid then returns to the evaporating chamber, creating a cycle of repeated heat dissipation.

### FIELD OF THE INVENTION

The present invention relates to a heat dissipation device, and more particularly, to a water-cooled heat dissipation device.

### BACKGROUND OF THE INVENTION

“Phase-change heat dissipation” utilizes a liquid medium capable of undergoing phase changes to absorb heat and evaporate into a gas medium at a specific temperature. The resulting gas medium condenses and releases heat as a liquid medium at another location, thereby achieving a method of heat transfer through a cooling process. Therefore, the “phase-change heat dissipation device” is typically installed on heat sources such as the GPU (Graphics Processing Unit) of a computer's graphics card or the CPU (Central Processing Unit) of a motherboard.

Traditional phase-change heat dissipation devices 90 are typically positioned on the top surface of a heat source 80, as shown in FIG. 10, and generally consist of an evaporator 91, a condenser 92, and a condensation tube 93. The condensation tube 93 is connected to an evaporating chamber 911 of the evaporator 91, and the evaporating chamber 911 is filled with liquid medium “a”. The condenser 92 has a condensation chamber 921 filled with cooling water “c”. The liquid medium “a” absorbs heat from the heat source 80 and evaporates into a gas medium “b”, and the gas medium “b” rises through the condensation tube 93 to the condensation chamber 921 of the condenser 92 for heat release and condensation.

Since the condensation tube 93 generally extends vertically straight from the evaporator 91 and vertically enters the condenser 92, it is affected by the horizontal interface 94 where the evaporator 91 and condenser 92 meet. This interference is unfavorable for the condensation of gas medium “b” back into liquid medium “a” within the evaporating chamber 911, as indicated by the dashed arrow in FIG. 10. This, in turn, affects the efficiency of heat dissipation. In other words, the direct connection between the evaporating chamber 911 and the condensation chamber 921 within the condensation tube 93 and condenser 92 leads to slow condensation of gas medium b and inadequate heat dissipation performance.

The present invention intends to provide a water-cooled heat dissipation device to eliminate the shortcomings mentioned above.

### SUMMARY OF THE INVENTION

The present invention relates to a water-cooled heat dissipation device and comprises an evaporator having an evaporating chamber filled with a liquid medium. A water cooler has a cooling chamber filled with cooling water. At least one condensation tube has a lower end thereof connected to the evaporating chamber. The at least one condensation tube is inclined an angle relative to a vertical line. An upper end of the at least one condensation tube extends into the cooling chamber. A portion of the at least one condensation tube is immersed in the cooling water of the cooling chamber. The liquid medium in the evaporating chamber absorbs heat from a heat source and forms a gas medium that rises into the at least one condensation tube. The cooling water within the cooling chamber causes the gas medium in the at least one condensation tube to condense into the liquid medium. The liquid medium falls into the evaporating chamber to cool the heat source.

Preferably, the water cooler has an outside that has a first outlet and a first inlet. A heat exchanger has a second inlet and a second outlet. The first outlet is connected to the second inlet through a first conduit. The first inlet is connected to the second outlet through a second conduit. A water pump is placed on the first conduit or the second conduit.

Preferably, the cooling chamber of the water cooler includes multiple partition plates which divide the cooling chamber into a water channel. There are multiple condensation tubes which have their upper ends extend into the water channel. Two ends of the water channel are respectively connected to the first inlet and the first outlet.

Preferably, a gap is formed between a top of the evaporator and an underside of the water cooler. The at least one condensation tube passes through the gap. The height of the gap is less than half of the total length of the at least one condensation tube.

The primary object of the present invention is to provide a water-cooled heat dissipation device which uses at least one inclined condensation tube and an independent water cooler to efficiently guide liquid condensed from gas to return to the evaporating chamber, creating a cycle of repeated heat dissipation.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is a perspective view to show the first embodiment of the water-cooled heat dissipation device of the present invention;

FIG. 2 is an exploded view to show the first embodiment of the water-cooled heat dissipation device of the present invention;

FIG. 3 is a cross sectional view of the water cooler of the present invention;

FIG. 4 is a cross sectional view of the first embodiment of the water-cooled heat dissipation device of the present invention;

FIG. 5 is another cross sectional view of the first embodiment of the water-cooled heat dissipation device of the present invention, wherein water is not yet filled into the water-cooled heat dissipation device;

FIG. 6 is another cross sectional view of the second embodiment of the water-cooled heat dissipation device of the present invention, wherein water is not yet filled into the water-cooled heat dissipation device;

FIG. 7 is an exploded view to show the third embodiment of the water-cooled heat dissipation device of the present invention;

FIG. 8 is a cross sectional view of the third embodiment of the water-cooled heat dissipation device of the present invention, wherein water is not yet filled into the water-cooled heat dissipation device;

FIG. 9 shows a fourth embodiment of the water-cooled heat dissipation device of the present invention, and

FIG. 10 shows a conventional phase-change heat dissipation device.

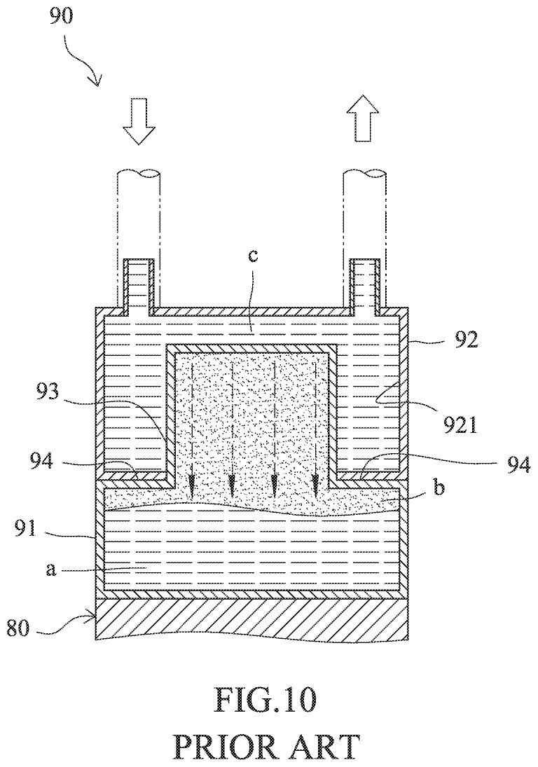

### DETAILED DESCRIPTION OF THE PREFERRED EMBODIMENT

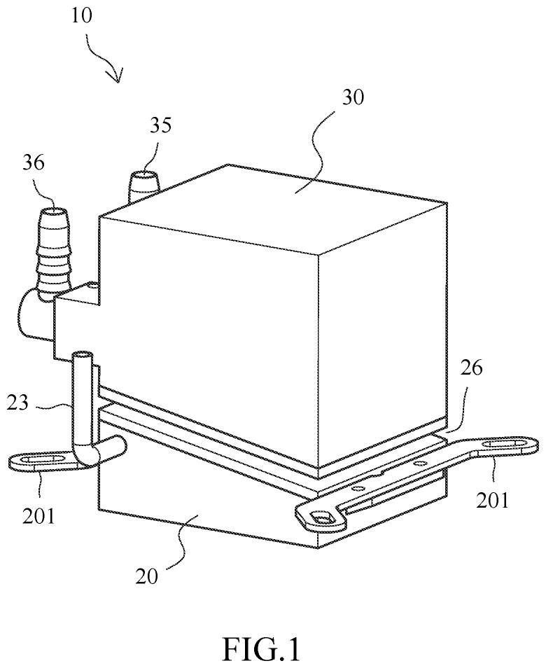

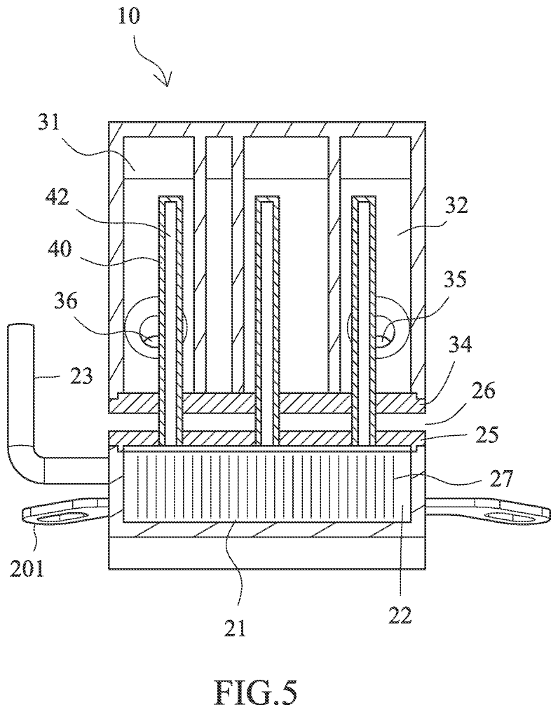

Referring to FIGS. 1-8, the water-cooled heat dissipation device 10 of the present invention comprises an evaporator 20, a water cooler 30 and one or more than one condensation tube 40. This embodiment shows embodiments with multiple condensation tubes 40. Each condensation tube 40 is a flat and rectangular body and has an evaporating chamber 21. A heat dissipation member 27 and a phase-change medium 22 are located in the evaporating chamber 21 as shown in FIG. 5. In this embodiment, the heat dissipation member 27 is a capillary heat dissipation strip, and the phase-change medium 22 is cooling medium. A feeding tube 23 is connected to the evaporator 20 and communicates with the evaporating chamber 21 so as to feed the cooling medium 22 into the evaporating chamber 21. The multiple condensation tubes 40 their lower ends communicate with the evaporating chamber 21. Two side arms 201 extend from each of two sides of the evaporator 20.

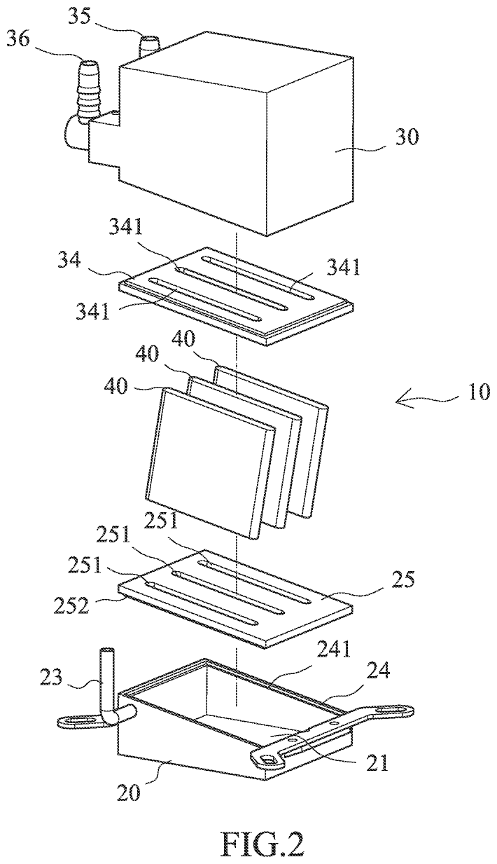

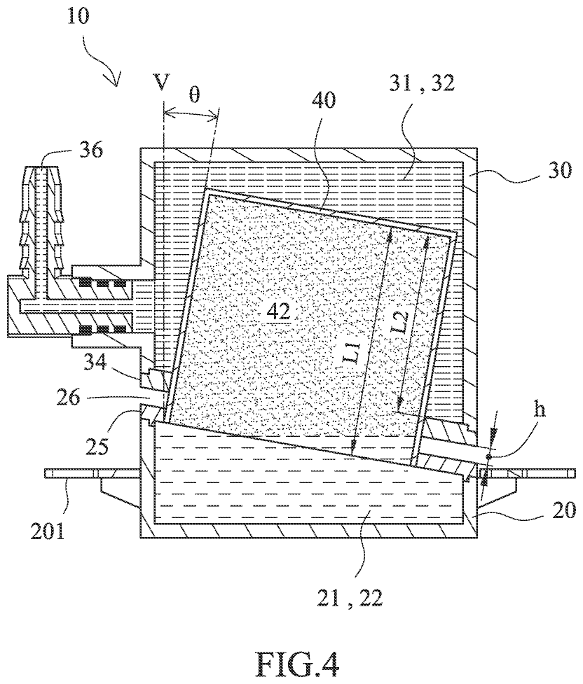

The water cooler 30 has a cooling chamber 31 filled with cooling water 32 as shown in FIG. 2. The condensation tubes 40 each are inclined an angle “θ” relative to a vertical line “V” as shown in FIG. 4, and the upper end of each condensation tube 40 extends into the cooling chamber 31. A portion of each of the condensation tubes 40 is immersed in the cooling water 32 of the cooling chamber 31. The liquid medium 22 in the evaporating chamber 21 absorbs heat from heat source and forms a gas medium 22 that rises into the condensation tubes 40. The cooling water 32 within the cooling chamber 31 causes the gas medium 22 in the condensation tubes 40 to condense into the liquid medium 22 and the liquid medium 22 easily falls into the evaporating chamber 21 to cool the heat source 80.

The angle “θ” of inclination of each condensation tube 40 is between 8 to 16 degrees. Specifically, the angle “θ” of inclination of each condensation tube 40 is 10 to 12 degrees. Preferably, the angle “θ” of inclination of each condensation tube 40 is 10 degrees. This arrangement effectively guide the liquid medium 22 that is condensed from the gas medium 22 to flow into the evaporating chamber 21 to absorb heat and enhance the efficiency of heat dissipation.

As shown in FIG. 2, the evaporator 20 has a first opening 24 formed to the top thereof, and the first opening 24 communicates with the evaporating chamber 21. The first opening 24 is covered by an inclined first cover 25 which has multiple first holes 251. The condensation tubes 40 are installed in the first holes 251 of the first cover 25. The condensation tubes 40 are perpendicular to a plane of the first cover 25. The evaporator 20 includes a groove 241 defined in the inner side thereof, and a protrusion 252 is formed to the underside of the first cover 25. The protrusion 252 fits into the groove 241 to connect the first cover 25 to the evaporator 20.

The length “L2” that the portion of each of the condensation tubes 40 extends into the cooling chamber 31 is more than half of the total length “L1” of each condensation tube 40. This ensures that a large area of each condensation tube 40 is merged into the cooling water 32 to provide higher dissipation efficiency to the gas medium 22 in each condensation tube 40.

As shown in FIG. 4, a gap 26 is formed between the top of the evaporator 20 and the underside of the water cooler 30. The condensation tubes 40 pass through the gap 26. The height “h” of the gap 26 is less than half of the total length “L1” of each condensation tube 40. Preferably, the height “h” of the gap 26 is less than one third of the total length “L1” of each condensation tube 40. By the gap 26, the underside of the water cooler 30 does not absorb heat from the top of the evaporator 20 to avoid the gas medium 22 from entering into the condensation tubes 40 due to low temperature. The height “h” of the gap 26 is less than half of the total length “L1” of each condensation tube 40 makes the combination of the evaporator 20 and the water cooler 30 be compact and occupies less space.

As shown in FIGS. 2 to 4, at the underside of the water cooler 30, there is a second opening 33 that connects to the cooling chamber 31 of the water cooler 30. Inside this second opening 33, a second cover 34 with an inclined placement is installed. The upper ends of the multiple condensation tubes 40 pass through second holes 341 of the second plate 34 and extend into the cooling chamber 31.

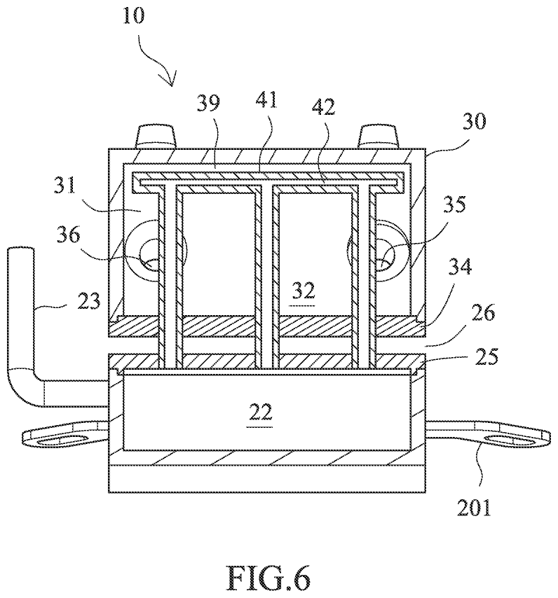

As shown in FIG. 6 which shows the second embodiment of the present invention, wherein the difference between the first and second embodiments is that the upper end of each condensation tube 40 has a condensation block 41 which is located within the cooling chamber 31 and includes an inner room 42. The inner room 42 of each condensation tube 40 communicates with the evaporating chamber 21. Specifically, the upper end of each condensation tube 40 has a condensation block 41 that is integrally formed to the condensation tube 40. Thea cross-sectional area of the inner room 42 is larger than that of each condensation tube 40. The inner room 42 of the condensation block 41 communicates with the evaporating chamber 21 through each condensation tube 40. Furthermore, due to the condensation block 41 located within the cooling chamber 31 of the water cooler 30, the condensation block 41 increases the contact area between the multiple condensation tubes 40 and the cooling water 32. This accelerates the cooling of the inner room 42 and the gas medium 22 within the condensation tubes 40, thereby enhancing the cooling effect.

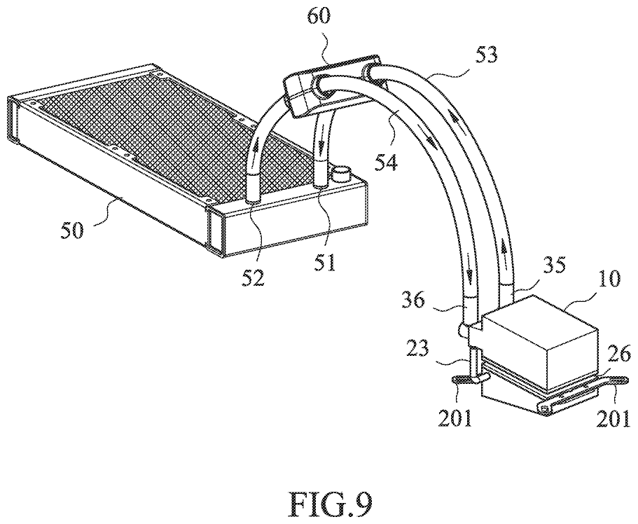

As shown in FIGS. 1 to 9, the present invention also provides a fourth embodiment of the water-cooled heat dissipation device 10. In this fourth embodiment, a heat exchanger 50 and a water pump 60 are introduced. Preferably, the heat exchanger 50 is equipped with a fan. The outer wall of the water cooler 30 is equipped with a first outlet 35 and a first inlet 36. On the heat exchanger 50, a second inlet 51 and a second outlet 52 are provided. The first outlet 35 is connected to the second inlet 51 through a first conduit 53, and the first inlet 36 is connected to the second outlet 52 through a second conduit 54. The water pump 60 is placed on either the first conduit 53 or the second conduit 54.

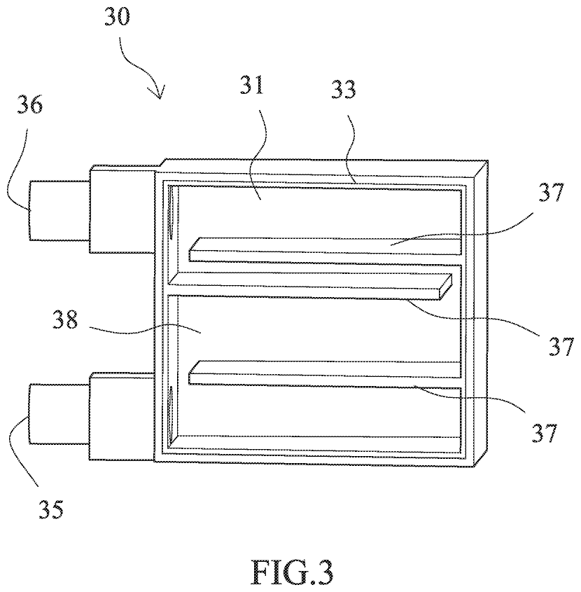

The cooling chamber 31 of the water cooler 30 includes multiple partition plates 37 as shown in FIGS. 3 and 5. One of two ends of each of the partition plates 37 is formed to the inside of the cooling chamber 31, and another one of the two ends of each partition plate 37 is a free end so as to divide the cooling chamber 31 into a zigzag water channel 38. The upper ends of the multiple condensation tubes 40 extend into the water channel 38. Two ends of the water channel 38 are respectively connected to the first inlet 36 and the first outlet 35. In other words, the water channel 38 are able to be connected to external pipes. By the water channel 38, and the upper ends of the multiple condensation tubes 40 extend into the water channel 38, the cooling water 32 of the cooling chamber 31 circulates to brings heat to the heat exchanger 50.

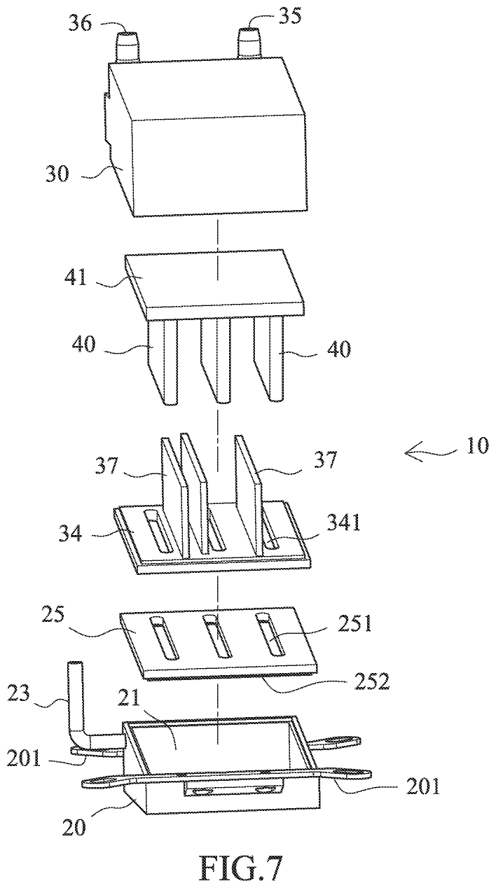

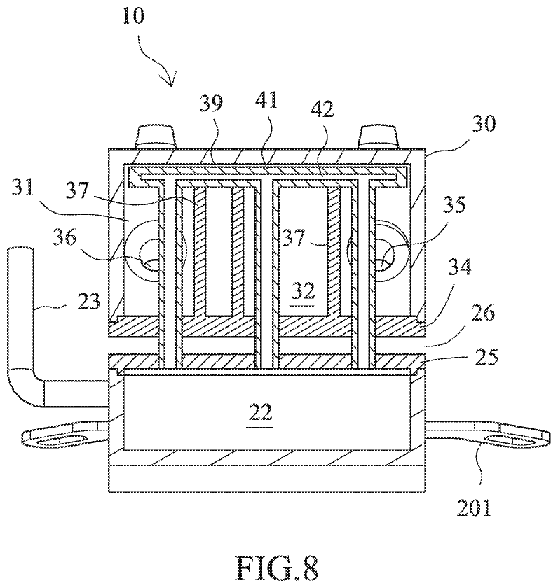

It is noted that in order to yield the condensation blocks 41 in the third embodiment of the water-cooled heat dissipation device 10, as shown in FIGS. 7 and 8, the lower ends of the partition plates 37 are integrally formed with the second cover 34, and a room 39 is formed between the upper ends of the partition plates 37 and the inside of cooling chamber 31, so that the condensation blocks 41 are located in the room 39.

The working principle of the water-cooled heat dissipation device 10 of the present invention are that the lower surface of the evaporator 20 is placed onto the heat source by means of the side arms 201, ensuring close contact with the heat-emitting surface, for instance, the upper surface of a GPU or CPU within a computer system. The heat source transfers heat to the evaporator 20, causing the liquid medium 22 within the evaporating chamber 21 to absorb heat and transform into a gas medium 22 that rises to the upper end of the condensation tubes 40. The cooling water 32 inside the cooling chamber 31 of the water cooler 30 cools the upper end of the condensation tubes 40, leading to condensation and the formation of liquid medium 22 within the tubes. This liquid then descends along the inner walls of the condensation tubes 40 into the evaporating chamber 21. Simultaneously, the water pump 60 operates to circulate the cooling water 32 between the cooling chamber 31, the first outlet 35, the first conduit 53, the second inlet 51, the heat exchanger 50, the second outlet 52, the second conduit 54, the water pump 60, and the first inlet 36. This circulation removes heat from the water-cooled heat dissipation device 10 and disperses it into the air through the heat exchanger 50.

The inclined placement of the condensation tubes 40 facilitates the downward flow of the liquid medium 22 formed after the condensation of the gas medium 22 along the inner walls of the condensation tubes 40 due to upward inclination. This design enables the liquid medium 22 to flow back into the evaporating chamber 21 for reheating and evaporation, ultimately enhancing the efficiency of heat dissipation. Additionally, the utilization of an independent water cooler 30 with condensation tubes 40 extending into the cooling chamber 31 and partially immersed in the cooling water 32 accelerates the condensation speed of the gas medium 22 by allowing the cooling water 32 to cool the condensation tubes 40. This results in improved and more efficient heat dissipation.

While we have shown and described the embodiment in accordance with the present invention, it should be clear to those skilled in the art that further embodiments may be made without departing from the scope of the present invention.

What is claimed is:

1. A water-cooled heat dissipation device comprising:
an evaporator having an evaporating chamber filled with a liquid medium;
a water cooler having a cooling chamber filled with cooling water;
at least one condensation tube having a lower end thereof connected to the evaporating chamber, the at least one condensation tube being inclined an angle relative to a vertical line, an upper end of the at least one condensation tube extending into the cooling chamber, and
wherein a portion of the at least one condensation tube is immersed in the cooling water of the cooling chamber, the liquid medium in the evaporating chamber absorbs heat from a heat source and forms a gas medium that rises into the at least one condensation tube, the cooling water within the cooling chamber causes the gas medium in the at least one condensation tube to condense into the liquid medium, the liquid medium falls into the evaporating chamber to cool the heat source.

2. The water-cooled heat dissipation device as claimed in claim 1, wherein the angle of inclination of the at least one condensation tube is between 8 to 16 degrees.

3. The water-cooled heat dissipation device as claimed in claim 2, wherein the evaporator has a first opening formed to a top thereof, the first opening communicates with the evaporating chamber, the first opening is covered by an inclined first cover which has a first hole, the at least one condensation tube is installed in the first hole of the first cover, the at least one condensation tube is perpendicular to a plane of the first cover.

4. The water-cooled heat dissipation device as claimed in claim 3, wherein the evaporator includes a groove defined in an inner side thereof, and a protrusion is formed to an underside of the first cover, the protrusion fits into the groove.

5. The water-cooled heat dissipation device as claimed in claim 1, wherein a length that the portion of the at least one condensation tube extends into) the cooling chamber is more than half of a total length of the at least one condensation tube, a heat dissipation member is installed within the evaporating chamber.

6. The water-cooled heat dissipation device as claimed in claim 1, wherein a gap is formed between a top of the evaporator and an underside of the water cooler, the at least one condensation tube passes through the gap, a height of the gap is less than half of the total length of the at least one condensation tube.

7. The water-cooled heat dissipation device as claimed in claim 1, wherein the cooling chamber of the water cooler includes multiple partition plates, the partition plates divide the cooling chamber into a water channel, there are multiple condensation tubes which have their upper ends extend into the water channel, an inlet and an outlet of the water channel are adapted to be connected to external pipes.

8. The water-cooled heat dissipation device as claimed in claim 7, wherein the upper end of the at least one of the condensation tubes has a condensation block which is located within the cooling chamber and includes an inner room, a cross-sectional area of the inner room is larger than that of the at least one condensation tube, the inner room is connected to the evaporating chamber through the at least one condensation tube.

9. The water-cooled heat dissipation device as claimed in claim 1, wherein the water cooler has an outside that has a first outlet and a first inlet, a heat exchanger has a second inlet and a second outlet, the first outlet is connected to the second inlet through a first conduit, the first inlet is connected to the second outlet through a second conduit, a water pump is placed on the first conduit or the second conduit.

10. The water-cooled heat dissipation device as claimed in claim 9, wherein the cooling chamber of the water cooler includes multiple partition plates, the partition plates divide the cooling chamber into a water channel, there are multiple condensation tubes, and upper ends of the multiple condensation tubes extend into the water channel, two ends of the water channel are respectively connected to the first inlet and the first outlet.
